(19) United States
(12) Patent Application Publication
(10) Pub. No.: US 2026/0164805 A1
(43) Pub. Date: Jun. 11, 2026

(54) INTEGRATED CIRCUIT INCLUDING PARALLEL DYNAMIC REGISTERS, OPERATION CHIP, AND COMPUTING APPARATUS

(71) Applicant: SHENZHEN MICROBT ELECTRONICS TECHNOLOGY CO., LTD., SHENZHEN, GUANGDONG (CN)

(72) Inventors: Wenbo TIAN, SHENZHEN, GUANGDONG (CN); Chuan GONG, SHENZHEN, GUANGDONG (CN); Nan LI, SHENZHEN, GUANGDONG (CN); Haifeng GUO, SHENZHEN, GUANGDONG (CN); Zuoxing YANG, SHENZHEN, GUANGDONG (CN)

(73) Assignee: SHENZHEN MICROBT ELECTRONICS TECHNOLOGY CO., LTD., SHENZHEN, GUANGDONG (CN)

(21) Appl. No.: 18/724,348

(22) PCT Filed: Jan. 9, 2024
(86) PCT No.: PCT/CN2024/071242

§ 371 Date: Jun. 26, 2024

(30) Foreign Application Priority Data
Mar. 30, 2023 (CN) 202310357471.7

(51) Int. Cl. H10D 89/10; G06F 1/20; G06F 1/26; H05K 7/20; H10W 20/41

(52) U.S. Cl. CPC H10D 89/10; G06F 1/206; G06F 1/26; H05K 7/2039; H10W 20/427

(57) ABSTRACT

The present disclosure relates to an integrated circuit including parallel dynamic registers, an operation chip, and a computing apparatus. The integrated circuit includes a plurality of dynamic registers arranged in one column. The plurality of dynamic registers have respective input data signals and output data signals, and receive a same control signal. The plurality of dynamic registers include a first dynamic register arranged in a first row and a second dynamic register arranged in a second row adjacent to the first row. The first dynamic register includes a first tristate gate, and the second dynamic register includes a second tristate gate. The first tristate gate includes a first field effect transistor (FET), and the second tristate gate includes a second FET with a same polarity as the first FET. The first FET is adjacent to the second FET. The first FET and the second FET use a first polysilicon pattern continuously extending across a first boundary between the first row and the second row as a gate terminal to receive a same first control signal.

### CROSS-REFERENCE TO RELATED APPLICATIONS

This application claims priority to Chinese Patent Application No. 202310357471.7, filed on Mar. 30, 2023, which is incorporated herein by reference in its entirety.

### TECHNICAL FIELD

The present disclosure relates to the field of circuit design and layout, and more particularly, to an integrated circuit including parallel dynamic registers, an operation chip, and a computing apparatus.

### BACKGROUND

The register is widely used in digital circuit design, e.g., is available for registering, shifting, and frequency division of the digital signal. When a plurality of registers are needed to operate synchronously, the plurality of registers may be connected in parallel, and synchronous clock control signals may be provided for various registers, thereby enabling to reduce the area of the implemented digital circuit chip and to reduce the power consumption. Registers may be classified into dynamic registers and static registers. Compared with a static register, the positive feedback circuit for maintaining the operating state is reduced for a dynamic register, so the circuit structure can be greatly simplified, which can further reduce the chip area and the power consumption. However, since there is no positive feedback circuit in the dynamic register to lock the internal operating state, the voltage can be maintained only by the parasitic capacitance of the floating node. If the leakage current of the device at this node is large, the lowest operating frequency of the dynamic register can be limited.

Therefore, an optimized parallel dynamic register circuit is needed to reduce the impact of the leakage current on the lowest operating frequency of the dynamic register.

### SUMMARY

According to a first aspect of the present disclosure, an integrated circuit is provided, including: a plurality of dynamic registers arranged in one column. The plurality of dynamic registers have respective input data signals and output data signals, and receive a same control signal. The plurality of dynamic registers include a first dynamic register arranged in a first row and a second dynamic register arranged in a second row adjacent to the first row. The first dynamic register includes a first tristate gate, and the second dynamic register includes a second tristate gate. The first tristate gate includes a first field effect transistor (FET), and the second tristate gate includes a second FET with a same polarity as the first FET. The first FET is adjacent to the second FET. The first FET and the second FET use a first polysilicon pattern continuously extending across a first boundary between the first row and the second row as a gate terminal to receive a same first control signal.

According to a second aspect of the present disclosure, an operation chip is provided, including at least one integrated circuit as described above.

According to a third aspect of the present disclosure, a computing apparatus is provided, including: at least one operation chip as described above, a control chip, a power supply module, and a radiator. The control chip is coupled to the at least one operation chip and is configured for controlling operation of the at least one operation chip, the power supply module is configured for providing power to the at least one operation chip and/or the control chip, and the radiator is configured for dissipating heat for the at least one operation chip, the control chip, and/or the power supply module.

According to the following descriptions with reference to the accompanying drawings, other characteristics, features, and advantages of the present disclosure become clear.

### BRIEF DESCRIPTION OF THE DRAWINGS

The included accompanying drawings are for illustrative purpose and are only used for providing examples of possible structures and arrangements of the inventive apparatus and the method of applying it to a computing apparatus disclosed herein. These accompanying drawings in no way limit any changes in form and detail that may be made to the implementations by one skilled in the art without departing from the essence and scope of the implementations. The implementations will be easier to be understood by the following detailed description in combination with the accompanying drawings, wherein similar reference numerals represent similar structural elements.

FIG. 1 is a composition block diagram of an integrated circuit including parallel dynamic registers according to an embodiment of the present disclosure.

FIG. 2 is a circuit diagram example of a dynamic register according to an embodiment of the present disclosure.

FIG. 3 is another circuit diagram example of a dynamic register according to an embodiment of the present disclosure.

FIG. 4 is a layout example of an integrated circuit including parallel dynamic registers according to an embodiment of the present disclosure.

FIG. 5 is another layout example of an integrated circuit including parallel dynamic registers according to an embodiment of the present disclosure.

FIG. 6 is still another layout example of an integrated circuit including parallel dynamic registers according to an embodiment of the present disclosure.

FIG. 7 is a schematic diagram of an operation chip and a computing apparatus according to an embodiment of the present disclosure.

It is noted that in the implementations illustrated in the following, sometimes a same reference numeral is used in different accompanying drawings to represent a same part or parts with a same function, and repeated description thereof is omitted. In the present specification, similar numbers and letters are used for representing similar items. Therefore, once an item is defined in an accompanying drawing, the item in subsequent accompanying drawings will not be further discussed.

For ease of understanding, locations, sizes, scopes and the like of various structures shown in the accompanying drawings and the like sometimes do not represent the actual locations, sizes, scopes and the like. Therefore, the disclosed invention is not limited to the locations, the sizes, the scopes and the like disclosed in the accompanying drawings and the like. In addition, the accompanying drawings are not necessarily drawn to scale, and some features may be exaggerated to show the details of the specific components.

### DETAILED DESCRIPTION

Now various exemplary embodiments of the present disclosure are described in detail with reference to the accompanying drawings. It should be noted that unless illustrated in detail otherwise, the relative arrangements of the components and steps, the numerical expressions, and the values stated in these embodiments do not limit the scope of the present disclosure.

In fact, the following descriptions of at least one exemplary embodiment are merely illustrative, and in no way put any limitation on the present disclosure and the application or use thereof. That is, the structures and the methods herein are shown in an exemplary manner to illustrate different embodiments of the structures and the methods in the present disclosure, instead of intending to be limitations. One skilled in the art would understand that they only illustrate the exemplary manners for implementing the present disclosure, rather than in exhaustive manners. In addition, the accompanying drawings are not necessarily drawn to scale, and some features may be exaggerated to show the details of the specific components.

Technologies, methods, and apparatuses known to a person of ordinary skill in the related art may not be discussed in detail, but in proper circumstances, the technologies, methods, and devices shall be regarded as a part of the allowed specification.

As mentioned above, the lowest operating frequency of the dynamic register is limited by the leakage current of the device at the floating node within the register. The dynamic register may be implemented by the tristate gate circuit (hereinafter referred to as “tristate gate” for short). There are three states of the output of the tristate gate: the high-level state, the low-level state, and the high-impedance state. The tristate gate has the enable control terminal for receiving the control signal. Under the action of the control signal, the tristate gate is turned on and outputs a high level or a low-level according to the input, or the tristate gate is turned off and its output terminal exhibits a high-impedance state. When the tristate gate is in the high-impedance state, the leakage current at its output terminal determines the lowest frequency at which the dynamic register implemented by the tristate gate can operate. Compared with other gate circuits (such as the transmission gate circuit), the dynamic register implemented by using the tristate gate circuit can reduce the leakage current to some extent. However, it is still desirable to further reduce the leakage current to alleviate the limitation on the lowest operating frequency of the dynamic register.

On the other hand, in the layout design method based on the standard cell library, the layout of the polysilicon pattern used as the gate is very important. For example, the standard layout usually follows the design principle of equal heights and variable widths, and the layout width is calculated based on the number of CPPs and the minimum center distance (CPP) between two gate polysilicon patterns. For two cells in two adjacent rows, the existing layout design method usually makes the gate polysilicon patterns of these two cells to be separated. That is, the gate polysilicon patterns of the two cells in the two adjacent rows are discontinuous at the cross-row boundary.

The inventors of the present disclosure recognize that for parallel dynamic register circuits implemented by using tristate gates, in the layout design, a plurality of dynamic register circuits may be located in one column, meanwhile the gate polysilicon patterns of two field effect transistors (FETs) with the same polarity in the tristate gates in the adjacent rows for receiving the same control signal are no longer separated, but exist as a whole continuously extending across the boundary, thereby utilizing the local layout effect (LLE) to reduce the leakage currents of the tristate gates in these two rows in the high-impedance state, further alleviating the limitation on the lowest operating frequency of the dynamic register. The following will describe specific embodiments according to the present disclosure in detail.

FIG. 1 exemplarily shows a composition block diagram of an integrated circuit 100 including parallel dynamic registers according to an embodiment of the present disclosure. The integrated circuit 100 includes a plurality of registers 102-1, 102-2, 102-3 . . . 102-N (which may be collectively referred to as “register 102”). N may be any integer greater than or equal to 2. Among the plurality of dynamic registers connected in parallel, each dynamic register 102 may have its own independent input data signal 101 and output data signal 103, but be controlled by the same control signal 106. The input data signal 101 may be represented as D [N:1], wherein the i^{th} (1≤i≤N) bit of the data is received by the i^{th} dynamic register (102-i). The output data signal 103 may be represented as Q [N:1], wherein the i^{th} (1≤i≤N) bit of the data is output from the i^{th} dynamic register (102-i). In some embodiments, the integrated circuit 100 may further include a buffer 104 for splitting the control signal 106 into the complementary first control signal 105-1 and second control signal 105-2. Each dynamic register 102 changes the operating state under the control of the first control signal 105-1 and the second control signal 105-2. When the first control signal 105-1 and the second control signal 105-2 exhibit the first state (including a level state or an edge state), each dynamic register 102 holds the data and is in the register state; while when the first control signal 105-1 and the second control signal 105-2 exhibit the second state (including a level state or an edge state), the output of each dynamic register 102 changes following the input and each dynamic register 102 is in the read-out state. In some cases, unlike that shown in FIG. 1, the buffer 104 may exist dependently of each dynamic register 102 and be incorporated into each register 102. At this time, each register 102 is directly controlled by the same control signal 106. However, inside each register 102, the corresponding buffer 104 may still be utilized to split the control signal 106 into the complementary control signals 105-1 and 105-2. The control signals 105-1, 105-2, and 106 may be clock control signals, e.g., generated by the clock circuit, or may be other enable control signals. Depending on the specific constitution of the register 102, the control signals 105-1, 105-2, and 106 may be used for implementing the level triggering or may implement the edge triggering.

The dynamic register 102 may include various register forms including the tristate gate, e.g., a flip-flop, a latch and the like. The difference lies in that the flip-flop is triggered using the edge change of the clock signal, while the latch is triggered according to the low and high signal levels. Compared with the flip-flop, the dynamic register in the form of latch has the advantages of simple circuit structure, small area, and low power consumption.

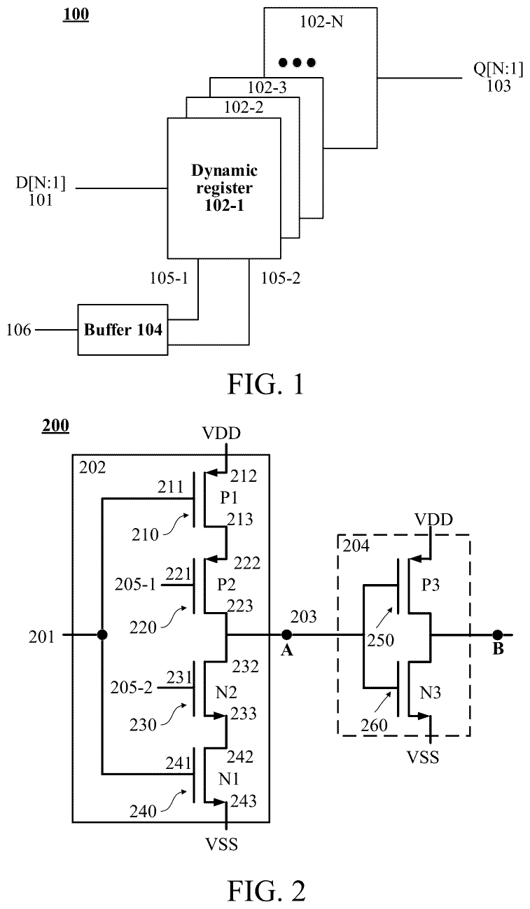

FIG. 2 shows an exemplary circuit implementation of a dynamic register according to an embodiment of the present disclosure. The dynamic register 200 may be used for implementing one or more dynamic registers 102 in the integrated circuit 100 of FIG. 1. The dynamic register 200 may include at least the tristate gate 202. The tristate gate 202 receives the input data signal 201 and the complementary control signals 205-1 and 205-2, and may provide the output data signal 203 at node A. The tristate gate 202 includes a pair of field effect transistors (FETs) with opposite polarities, P2 220 and N2 230 respectively. P2 is a P-type FET, and N2 is an N-type FET. The gate 221 of P2 220 and the gate 231 of N2 230 are used for receiving the pair of complementary control signals 205-1 and 205-2, respectively. The control signals 205-1 and 205-2 are used for controlling the operating state of the dynamic register 102. The drain 223 of P2 220 and the drain 232 of N2 230 are coupled together as the data output terminal to provide the output data signal 203. The tristate gate 202 further includes another pair of FETs with opposite polarities, P1 210 and N1 240 respectively. The gate 211 and the gate 241 thereof are coupled together as the data input terminal to receive the input data signal 201. P1 is a P-type FET, and N1 is an N-type FET.

These four FETs in the tristate gate 202 are connected in series from the power supply VDD to the ground VSS in the sequence of P 1 210, P2 220, N2 230, and N1 240. The source 212 of P1 is coupled to the power supply VDD, and the drain 213 of P1 is connected to the source 222 of P2. The source 233 of N2 is coupled to the drain 242 of N1, and the source 243 of N1 is coupled to the ground VSS.

In some embodiments, the pair of complementary control signals 205-1 and 205-2 may be a pair of differential clock signals CLK P and CLK N. In the circuit shown in FIG. 2, the gate 221 of P2 220 may receive CLK N, and the gate 231 of N2 230 may receive CLK P; or conversely, the gate 221 of P2 220 may receive CLK P, and the gate 231 of N2 230 may receive CLK N.

In other embodiments, the receiving positions of the input data signal 201 and the control signals 205-1 and 205-2 may be adjusted. For example, the control signals 205-1 and 205-2 may be received at the gate 211 of P1 210 and the gate 241 of N1 240 respectively, and the gate 221 of P2 220 and the gate 231 of N2 230 may be coupled together as the data input terminal to receive the input data signal 201.

Although the tristate gate 202 shown in FIG. 2 is a tristate gate inverter, in other embodiments, the tristate gate may be implemented to provide an in-phase output. Alternatively, to obtain the in-phase signal, an inverter 204 may also be coupled to the dynamic register 200 after node A of the tristate gate 202 of FIG. 2. FIG. 2 gives an exemplary implementation of the inverter 204, wherein the gates of the pair of FETs 250 and 260 with opposite polarities are coupled together to receive the input signal, and the drains are coupled together to provide the inverted output signal. The source of the P-type FET P3 250 is connected to the power supply VDD, and the source of the N-type FET N3 260 is connected to the ground VSS. For the dynamic register 200, finally, the output data signal 203 is provided at node B through the output terminal of the inverter 204 (i.e., the drains of the FETs 250 and 260). The inverter 204 may also be implemented using other logic gate circuits. It should be recognized that the inverter 204 is not necessary for the dynamic register 200, but is optional.

By way of example only, the dynamic register 200 may be implemented as a latch. When the control signal 205-2 is at the high level and the control signal 205-1 is at the low level, the tristate gate is turned on, the input data signal 201 may be transmitted to the output terminal to provide the output data signal 203, and the register is in the read-out state. When the control signal 205-2 is at the low level and the control signal 205-1 is at the high level, the tristate gate is turned off and is in the high-impedance state, at this time the input data signal 201 cannot be transmitted to the output terminal to provide the output data signal 203, and the register remains in the previous state and is in the latched state.

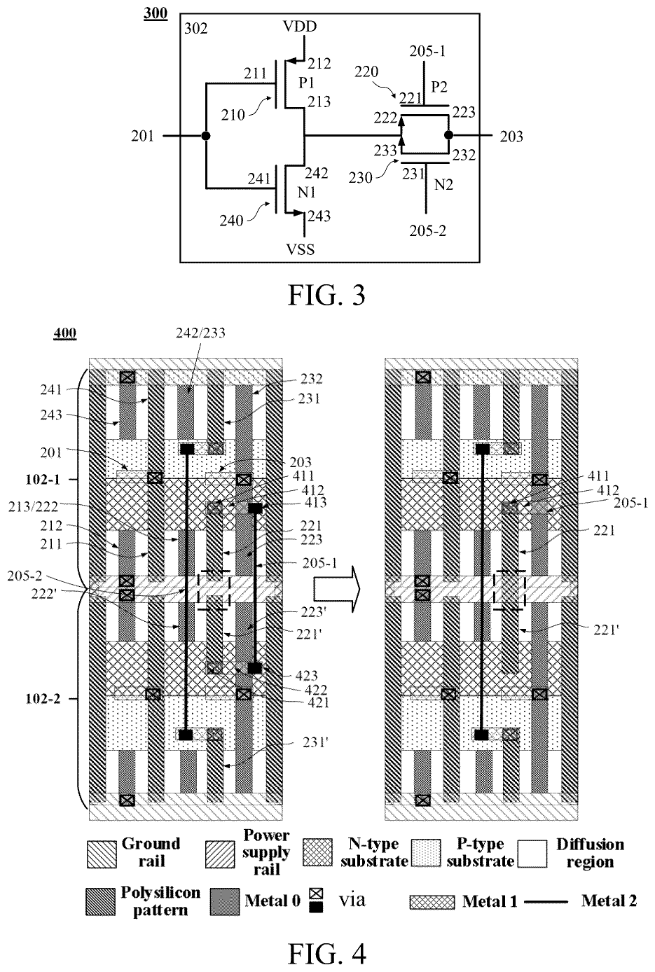

The dynamic register may also employ various other circuit implementations including the tristate gate. FIG. 3 shows another exemplary circuit implementation of the dynamic register according to an embodiment of the present disclosure. The dynamic register 300 may also be used for implementing one or more dynamic registers 102 in the integrated circuit 100 of FIG. 1. The dynamic register 300 may be used together with the dynamic register 200 of FIG. 2 to implement different dynamic registers 102 in the integrated circuit 100.

Similar to the dynamic register 200, the dynamic register 300 may also include at least the tristate gate 302. The tristate gate 302 includes the same circuit components as the tristate gate 202, and the difference lies only in the connection mode of the circuit components. Therefore, in illustration of the composition of the tristate gate 302, the same reference numerals as in FIG. 2 are used partially in FIG. 3. For example, as same as the tristate gate 202, the tristate gate 302 receives the input data signal 201 and the complementary control signals 205-1 and 205-2, and may provide the output data signal Q 203. The tristate gate 302 includes a pair of field effect transistors (FETs) with opposite polarities, P2 220 and N2 230 respectively. P2 is a P-type FET and N2 is an N-type FET. The gate 221 and the gate 231 thereof are used for receiving the pair of complementary control signals 205-1 and 205-2 respectively. The drain 223 of P2 220 and the drain 232 of N2 230 are coupled together as the data output terminal to provide the output data signal Q. The tristate gate 302 further includes another pair of FETs with opposite polarities, P1 210 and N1 240 respectively. The gate 211 and the gate 241 thereof are coupled together as the data input terminal to receive the input data signal 201. Pl is a P-type FET and N1 is an N-type FET. The drain 213 of P1 is coupled to the drain 242 of N1 and then is further coupled to the source 222 of P2 and the source 233 of N2.

The tristate gate 302 implemented in this way is also a tristate gate inverter. To obtain an in-phase signal, an inverter, such as the inverter 204 of FIG. 2, may further be connected to the dynamic register 300 at the output terminal of the tristate gate 302. The dynamic register 300 may also be implemented as a latch. When the control signal 205-2 is at the high level and the control signal 205-1 is at the low level, the tristate gate is turned on, the input data signal 201 can be transmitted to the output terminal to provide the output data signal 203, and the register is in the read-out state. When the control signal 205-2 is at the low level and the control signal 205-1 is at the high level, the tristate gate is turned off and is in the high-impedance state, at this time the input data signal 201 cannot be transmitted to the output terminal to provide the output data signal 203, and the register remains in the previous state, i.e., in the latched state.

FIG. 4 is a layout example of an integrated circuit 400 including parallel dynamic registers according to an embodiment of the present disclosure. The integrated circuit 400 may correspond to the integrated circuit 100 of FIG. 1. For convenience of description, the number of dynamic registers is set to 2, i.e., the dynamic register 102-1 and the dynamic register 102-2, and the circuit of the buffer 104 is omitted. Also for simplicity of description, both the dynamic register 102-1 and the dynamic register 102-2 are implemented using the logic circuit diagram of the tristate gate 202 shown in FIG. 2.

In the integrated circuit 400, the dynamic register 102-1 and the dynamic register 102-2 are arranged in one column. Also, the dynamic register 102-1 and the dynamic register 102-2 are in two adjacent rows. In the layout design and the manufacturing process of the integrated circuit, the sources and the drains of the FETs are implemented by layer 0 metal on the diffusion region in the substrate, and the gates are implemented by the polysilicon pattern. In the manufacturing process, the gate polysilicon pattern is generally etched into an elongated strip, but the gate polysilicon pattern may have other shapes.

For the layout of the dynamic register 102-1: the source 243, the gate 241, the drain 242/the source 233, the gate 231, and the drain 232 are located on the N-type diffusion region on the P-type substrate, corresponding to N1 and N2 in FIG. 2 respectively. The source 243 is coupled to the ground rail through a via to be connected to the ground VSS. The drain 242 and the source 233 are coupled together. The source 212, the gate 211, the drain 213/the source 222, the gate 221, and the drain 223 are located on the P-type diffusion region on the N-type substrate, corresponding to P1 and P2 in FIG. 2 respectively. The source 212 is coupled to the power supply rail through a via to be connected to the power supply VDD. The drain 213 and the source 222 are coupled together. The gate 211 and the gate 241 are coupled together and then connected to the input data signal 201 through a via and layer 1 metal. The drain 223 and the drain 232 are coupled together and then connected to the output data signal through a via and layer 1 metal. The P-type FET in which the gate 221 is located serves as one of the switch control tubes of the dynamic register 102-1, and is used for receiving one of the control signals for controlling the operating state (the read-out state or the register state) of the dynamic register 102-1, for example, the control signal 205-1.

The dynamic register 102-2 adopts the same logic circuit diagram as the dynamic register 102-1, and the layout designs of the two are also substantially identical. The difference mainly lies in that the P-type substrate is above the N-type substrate in the column direction, and correspondingly, the N-type FETs are above the P-type FETs in the column direction in the dynamic register 102-1; and the N-type substrate is above the P-type substrate in the column direction, and correspondingly, the P-type FETs are above the N-type FETs in the column direction in the dynamic register 102-2. In this way, the P-type FETs of the dynamic register 102-1 and the P-type FETs of the dynamic register 102-2 may be adjacent. The P-type FETs of the dynamic register 102-1 are arranged close to the row boundary between the dynamic registers 102-1 and 102-2, and the P-type FETs of the dynamic register 102-2 are also arranged close to the row boundary. They are separated only by the row boundary, and there is no other FET between them. The P-type FET composed of the source 222′, the gate 221′, and the drain 223′ in the dynamic register 102-2 corresponds to P2 in FIG. 2. The P-type FET in which the gate 221′ is located serves as one of the switch control tubes of the dynamic register 102-2, and is used for receiving one of the control signals for controlling the operating state (the read-out state or the register state) of the dynamic register 102-2, for example, the control signal 205-1. Both the gate 221′ and the gate 221 are used for receiving the same control signal. The P-type FET in which the gate 221′ is located and the P-type FET in which the gate 221 is located may be arranged to be adjacent, that is, opposite to each other and separated by the row boundary. Further, according to the standard cell layout design method, the P-type FET in which the gate 221′ is located and the P-type FET in which the gate 221 is located may be arranged to be aligned in the column direction. More particularly, the gate 221′ and the gate 221 may be arranged to be aligned in the column direction.

According to the traditional design conventions, the gate polysilicon patterns of the cells in different rows are separated, as shown in the dashed box in the left sub-diagram of FIG. 4. To connect the gate 221′ and the gate 221 to the same control signal, the gate 221′ and the gate 221 need to be led out to layer 1 metals 412 and 422 through vias 411 and 421 respectively, and then connected together through vias 413 and 423 and layer 2 metal to receive the common control signal.

By contrast, adjustment thereto has been made according to an embodiment of the present disclosure. As shown in the dashed box in the right sub-diagram of FIG. 4, the integrated circuit according to an embodiment of the present disclosure replaces the two originally separated polysilicon patterns with one complete polysilicon pattern extending across the row boundary. That is, the gate 221 and the gate 221′ share one gate polysilicon pattern. The local layout effect (LLE) caused by this local layout adjustment reduces the leakage currents of the dynamic registers 102-1 and 102-2 in the high impedance state, thereby alleviating the limitation on the lowest operating frequencies. In addition, after the gate 221 and the gate 221′ share one gate polysilicon pattern, the gate may be led out to the layer 1 metal 412 only through the via 411, thereby receiving the control signal 205-1. Compared with the left sub-diagram, the via 412, the layer 1 metal 422, the vias 413 and 423, and the layer 2 metal are omitted, thereby saving the wiring resource.

It should be recognized that the left and right sub-diagrams of FIG. 4 are provided only for describing the adjustment made to the gate polysilicon pattern of the embodiment of the present disclosure by contrast. Apart from the difference described above, the right sub-diagram of FIG. 4 is identical to the left sub-diagram of FIG. 4 in other respects and these aspects should not be regarded as prior or well-known technologies in the art. In addition, although in FIG. 4, the gate polysilicon pattern shared by the gate 221′ and the gate 221 extends in a direction parallel to the column direction, in other embodiments, the shared gate polysilicon pattern may be in other directions, for example, in a direction at an angle with the column direction.

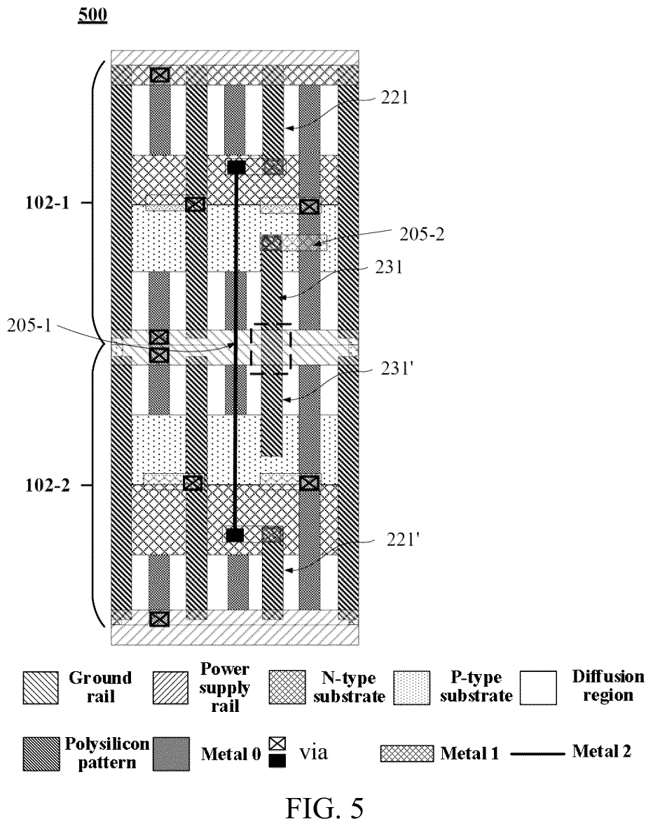

FIG. 4 shows an example in which two FETs for receiving the same control signal in the tristate gates of the dynamic registers in two adjacent rows share the polysilicon pattern continuously extending across the row boundary as the gate terminal, wherein the two FETs are P-type FETs. In other embodiments, the two FETs may also be N-type FETs. FIG. 5 shows a layout example of an integrated circuit 500 including parallel dynamic registers according to an embodiment of the present disclosure, wherein two N-type FETs share the polysilicon pattern continuously extending across the row boundary as the gate terminal. The difference from FIG. 4 lies in that in FIG. 5, the positions of the power supply rail and the ground rail are interchanged, the positions of the N-type substrates and the P-type substrates are interchanged, and correspondingly, the positions of the diffusion regions on the N-type substrates and the diffusion regions on the P-type substrates are also interchanged. The N-type FET in which the gate 231 is located in the tristate gate of the dynamic register 102-1 and the N-type FET in which the gate 231′ is located in the tristate gate of the dynamic register 102-2 are adjacent in position. The gate 231 and the gate 231′ use the polysilicon pattern continuously extending across the row boundary as the gate terminal to receive the same control signal 205-2.

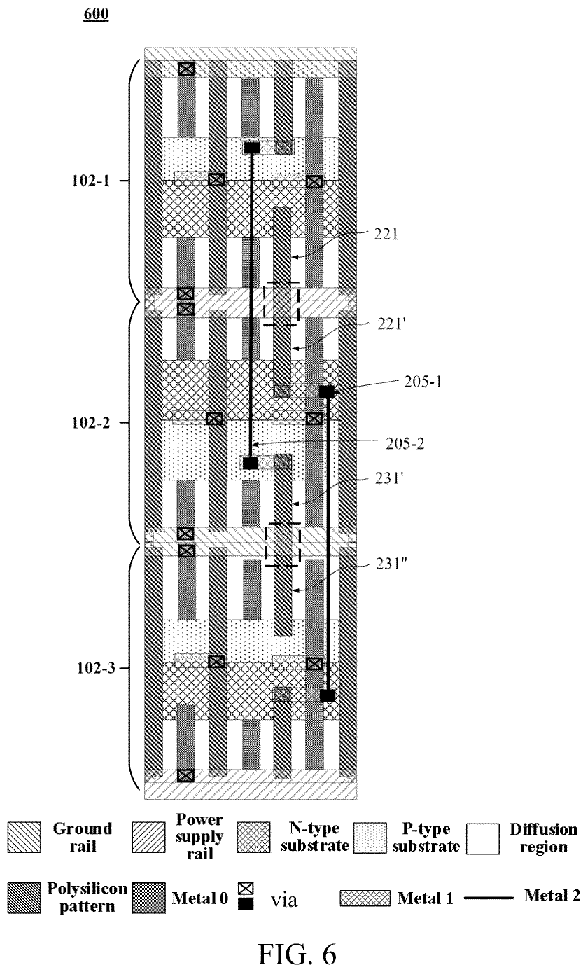

In addition to the two P-type FETs sharing the gate polysilicon pattern shown in FIG. 4 and the two N-type FETs sharing the gate polysilicon pattern shown in FIG. 5, in some embodiments, the integrated circuit according to an embodiment of the present disclosure may simultaneously implement the both. FIG. 6 shows a layout example of an integrated circuit 600 including parallel dynamic registers according to an embodiment of the present disclosure. The integrated circuit 600 includes at least the dynamic register 102-1, the dynamic register 102-2, and the dynamic register 102-3. The dynamic register 102-3 is arranged in the same column as the dynamic registers 102-1, 102-2, but in different rows. The dynamic register 102-3 is adjacent to the dynamic register 102-2, but not adjacent to the dynamic register 102-1. The layout designs of the dynamic register 102-1 and the dynamic register 102-2 are identical to that of FIG. 4, wherein the P-type FET in which the gate 221 is located and the P-type FET in which the gate 221′ is located share the same polysilicon pattern to receive the common control signal 205-1. The dynamic register 102-3 includes the tristate gate that may be implemented in the manner described above in combination with FIGS. 2-3. The tristate gate of the dynamic register 102-3 includes an N-type FET with the opposite polarity to the P-type FET in which the gate 221 is located, for example, the N-type FET in which the gate 231″ is located. The tristate gate of the dynamic register 102-2 also includes an N-type FET, for example, the N-type FET in which the gate 231′ is located. As described above, in the dynamic register 102-2, the N-type substrate is above the P-type substrate in the column direction, and correspondingly, the P-type FETs are above the N-type FETs in the column direction. In the dynamic register 102-3, the P-type substrate is above the N-type substrate in the column direction, and correspondingly, the N-type FETs are above the P-type FETs in the column direction. Therefore, the N-type FETs in the dynamic register 102-3 are adjacent to the N-type FETs in the dynamic register 102-2. Thus, the N-type FET in which the gate 231′ is located is adjacent to the N-type FET in which the gate 231″ is located in position. The gate 231′ and the gate 231″ use the same polysilicon pattern to receive the common control signal 205-2. The control signal 205-2 is complementary to the control signal 205-1.

As shown in FIG. 6, the polysilicon pattern shared by the gate 221 and the gate 221′ and the polysilicon pattern shared by the gate 231′ and the gate 231″ may be aligned in the column direction. This is because the gates 221′ and 231′ of the two FETs with opposite polarities for receiving the complementary control signals respectively in the dynamic register 102-2 may be arranged to be aligned in the column direction. In some other embodiments, various shared polysilicon patterns may not be aligned in the column direction.

In some embodiments, the tristate gates of various dynamic registers 102 may adopt FETs with different polarities to receive the same complementary control signals respectively. Taking FIG. 4 as an example, in the dynamic register 102-1, the gate 221 of the P-type FET receives the control signal 205-1, and the gate 231 of the N-type FET receives the complementary control signal 205-2; in the dynamic register 102-2, the gate 221′ of the P-type FET receives the control signal 205-1, and the gate 231′ of the N-type FET receives the complementary control signal 205-2. The gate 221 and the gate 221′ share the gate polysilicon pattern, and the gate 231 and the gate 231′ are connected together through the via and the metal wiring. In the same way, in FIG. 5, the gate 231 of the N-type FET and the gate 231′ of the N-type FET share the gate polysilicon pattern to receive the control signal 205-2, and the gate 221 of the P-type FET and the gate 221′ of the P-type FET are connected together through the via and the metal wiring to receive the complementary control signal 205-1. Such a structure facilitates more gate polysilicon pattern sharing of FETs in adjacent rows when the number of the dynamic registers 102 is large.

In some embodiments, the FET in the tristate gate of the dynamic register 102 may include at least one of a junction field effect transistor (JFET) or a metal oxide semiconductor field effect transistor (MOSFET, hereinafter referred to as MOS for short). Further, the tristate gate of the dynamic register 102 may be implemented using the complementary MOSs (CMOSs), i.e., a P-type MOS (PMOS) and an N-type MOS (NMOS) appear in pairs. PMOS and NMOS may be used for receiving the complementary control signals respectively. Compared with the case in which PMOS and NMOS are not used in pairs, the integrated circuit implemented by CMOS can better reflect the advantage of sharing the gate polysilicon pattern, because the polysilicon pattern can be shared by the dynamic registers in every two adjacent rows.

In some embodiments, to facilitate manufacturing, two FETs sharing the gate polysilicon pattern may share the same substrate region. For example, in FIG. 4, the two N-type substrate regions separated by the row boundary may be one complete piece of large N-type substrate region extending across the row boundary. In this way, a piece of large N-well region across the row boundary may be directly formed during manufacturing, and a complete section of polysilicon pattern across the row boundary can be deposited and etched on the N-well region to serve as the gate terminal. Again, for example, in FIG. 5, the two P-type substrate regions separated by the row boundary may be one complete piece of large P-type substrate region extending across the row boundary. In this way, a complete piece of large P-type substrate region may be used directly or a piece of large P-well substrate region across the row boundary may be formed during manufacturing, and a complete section of polysilicon pattern across the row boundary can be deposited and etched on this region to serve as the gate terminal.

The dynamic registers to which the two FETs sharing the gate polysilicon pattern each belong may have the same logic circuit diagram or may have different logic circuit diagrams. For example, in FIGS. 4-6, the dynamic registers 102 sharing the gate polysilicon pattern all adopt the same logic circuit diagram, i.e., the logic circuit diagram in FIG. 2. In other embodiments, various dynamic registers 102 may be implemented using different logic circuit diagrams, as long as it is ensured that they each include the FETs with the same polarity, adjacent to each other in position and for receiving the same control signal. For instance, when the dynamic registers in two adjacent rows are implemented using the logic circuit diagrams of FIG. 2 and FIG. 3 respectively, the gate polysilicon pattern may still be shared by the two FETs with the same polarity that are adjacent to each other and for receiving the same control signal in the adjacent two rows, thereby optimizing the leakage current of the dynamic register and the lowest operating frequency, and saving the wiring resource. The advantage of using the same logic circuit diagram for each dynamic register is that the efficiency of layout design and manufacturing process can be improved, the procedure is simplified, and the time is saved.

In some embodiments, the two dynamic registers sharing the gate polysilicon pattern may share the power supply rail or the ground rail, to avoid the need for longer wiring by using the power supply rail or the ground rail respectively. Further, the shared power supply rail and the ground rail may be located at the row boundary of these two dynamic registers, thereby making the length of the connecting wiring from the power supply rail/ground rail to corresponding nodes in the two dynamic registers be as short as possible. If the two FETs sharing the gate polysilicon pattern are P-type FETs, the power supply rail can be shared between the two dynamic registers corresponding to the two FETs. For example, as shown in FIG. 4, the dynamic registers 102-1 and 102-2 may share the power supply rail and the power supply rail is located at the row boundary. If the two FETs sharing the gate polysilicon pattern are N-type FETs, the ground rail can be shared between the two dynamic registers corresponding to the two FETs. For example, as shown in FIG. 5, the dynamic registers 102-1 and 102-2 may share the ground rail and the ground rail is located at the row boundary.

According to some embodiments of the present disclosure, an integrated circuit is provided, including: a plurality of dynamic registers arranged in one column. The plurality of dynamic registers have respective input data signals and output data signals, and receive a same control signal. The plurality of dynamic registers include a first dynamic register arranged in a first row and a second dynamic register arranged in a second row adjacent to the first row. The first dynamic register includes a first tristate gate, and the second dynamic register includes a second tristate gate. The first tristate gate includes a first FET, and the second tristate gate includes a second FET with a same polarity as the first FET. The first FET is adjacent to the second FET. The first FET and the second FET use a first polysilicon pattern continuously extending across a first boundary between the first row and the second row as a gate terminal to receive a same first control signal.

In some embodiments, the first FET and the second FET are P-type field effect transistors or N-type field effect transistors.

In some embodiments, the plurality of dynamic registers further include a third dynamic register arranged in a third row adjacent to the second row but not adjacent to the first row. The third dynamic register includes a third tristate gate. The second tristate gate further includes a third FET with an opposite polarity to the first FET. The third tristate gate includes a fourth FET with the same polarity as the third FET. The third FET is adjacent to the fourth FET. The third FET and the fourth FET use a second polysilicon pattern continuously extending across a second boundary between the second row and the third row as a gate terminal to receive a same second control signal. The second control signal is complementary to the first control signal. In some embodiments, the first polysilicon pattern and the second polysilicon pattern are aligned in a column direction.

In some embodiments, the first tristate gate further includes a fifth FET, the second tristate gate further includes a third FET, the polarities of the fifth FET and the third FET are opposite to that of the first FET, gate terminals of the fifth FET and the third FET receive a second control signal complementary to the first control signal, and a drain terminal of the first FET and a drain terminal of the fifth FET are coupled together to provide the output data signal of the first dynamic register.

In some embodiments, the first tristate gate further includes a sixth FET and a seventh FET, a polarity of the sixth FET is opposite to that of the first FET, a polarity of the seventh FET is same as that of the first FET, a drain terminal of the seventh FET is coupled to a source terminal of the first FET, a drain terminal of the sixth FET is coupled to a source terminal of the fifth FET, gate terminals of the sixth FET and the seventh FET are coupled together to receive the input data signal of the first dynamic register, a source terminal of the sixth FET is coupled to one of a power supply rail or a ground rail, and a source terminal of the seventh FET is coupled to another one of the power supply rail or the ground rail.

In some embodiments, source terminals of the first FET and the fifth FET are coupled together.

In some embodiments, the first tristate gate and the second tristate gate have a same logic circuit diagram.

In some embodiments, the first FET and the second FET share a same substrate region continuously extending across the first boundary.

In some embodiments, the first dynamic register and the second dynamic register share one of a power supply rail or a ground rail, and the one of the power supply rail or the ground rail is arranged at the first boundary.

In some embodiments, the first dynamic register and the second dynamic register include a dynamic latch.

In some embodiments, the first tristate gate and the second tristate gate are implemented using complementary metal oxide semiconductor field effect transistors (CMOSs).

One skilled in the art would understand that the integrated circuit according to the present disclosure may be implemented by using a hardware description language (HDL) such as Verilog or VHDL. HDL description may be synthesized for a cell library designed for a given integrated circuit manufacturing technology, and may be modified for the reasons of timing, power, and others, so as to obtain a final design database that may be transferred to a factory to produce the integrated circuit by a semiconductor manufacturing system. The semiconductor manufacturing system may produce the integrated circuit by depositing a semiconductor material (for example, on a wafer that may include a mask), removing the material, changing the shape of the deposited material, modifying the material (for example, modifying the dielectric constant using ultraviolet processing or by doping the material), and the like. The integrated circuit may include the transistors and may also include other circuit elements (for example, the passive elements such as the capacitors, the resistors, the inductors and the like) and interconnections between the transistors and the circuit elements.

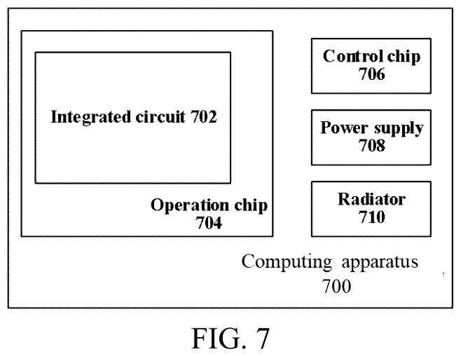

FIG. 7 exemplarily shows a schematic diagram of an operation chip and a computing apparatus according to an embodiment of the present disclosure.

According to an embodiment of the present disclosure, the operation chip is further provided. Referring to FIG. 7, the operation chip 704 includes at least one integrated circuit 702 as described above. In some embodiments, the operation chip 704 may include both the integrated circuit 702 that shares the gate polysilicon pattern as described above and other digital or analog integrated circuits that fully employ the standard layout design solution without adjustment. The operation chip 704 may be used for implementing relatively complex operation function, for example, to implement a certain algorithm (such as a hash algorithm). One skilled in the art would understand that although the operation chip 704 shown in FIG. 7 is a part of the computing apparatus 700, the operation chip 704 may also be used alone as an independent component.

According to an embodiment of the present disclosure, a computing apparatus is further provided, which may be used for executing an algorithm. Referring to FIG. 7, the computing apparatus 700 may include: at least one operation chip 704 as described above; a control chip 706; a power supply module 708; and a radiator 710. The control chip 706 is coupled to the at least one operation chip 704; the power supply module 708 may be used for providing power to the at least one operation chip 704 and the control chip 706; and the radiator 710 may be used for dissipating heat for the at least one operation chip 704, the control chip 706, and/or the power supply module 708. In a preferred embodiment, the computing apparatus 700, for example, may be used for executing the hash algorithm.

In all examples shown and discussed herein, any specific value should be interpreted only as an example and not as a limitation. Therefore, other examples of the exemplary embodiment may have different values.

As used herein, the term “exemplary” means “used as an example, instance, or illustration”, but is not intended to be a “model” to be accurately copied. Any implementation exemplarily described herein is not necessarily to be interpreted to be preferred or advantageous over other implementations. Moreover, the present disclosure is not limited by any stated or implied theory given in the technical field, background, summary or detailed description.

In addition, elements or features that are “connected” together may be mentioned in the description herein. As used herein, unless otherwise explicitly specified, “connected” means that one element/node/feature is directly connected to (or directly communicates with) another element/node/feature electrically, mechanically, logically, or in other manners.

In addition, the terms such as “first” and “second” may also be used herein for a reference purpose only, and therefore are not intended for a limitation. For example, the terms “first”, “second” and other such numerical terms relating to the structure or element do not imply the sequence or the order unless the context clearly indicates otherwise.

It should be further understood that the term “include/comprise”, when used herein, specifies the presence of the stated features, integers, steps, operations, units, and/or components, but does not preclude the presence or addition of one or more other features, integers, steps, operations, units, and/or components, and/or combinations thereof.

Although some specific embodiments of the present disclosure have been shown in detail through examples, one skilled in art should understand that the foregoing examples are only intended to be illustrative, but not to limit the scope of the present disclosure. One skilled in the art should understand that modifications may be made to the foregoing embodiments without departing from the scope and essence of the present disclosure. The scope of the present disclosure is defined by the appended claims.

1. An integrated circuit, comprising:
a plurality of dynamic registers arranged in one column, the plurality of dynamic registers having respective input data signals and output data signals, and receiving a same control signal, the plurality of dynamic registers comprising a first dynamic register arranged in a first row and a second dynamic register arranged in a second row adjacent to the first row, wherein the first dynamic register comprises a first tristate gate, the second dynamic register comprises a second tristate gate, the first tristate gate comprises a first field effect transistor (FET), the second tristate gate comprises a second FET with a same polarity as the first FET, the first FET is adjacent to the second FET, and the first FET and the second FET use a first polysilicon pattern continuously extending across a first boundary between the first row and the second row as a gate terminal to receive a same first control signal.

2. The integrated circuit according to claim 1, wherein the first FET and the second FET are P-type field effect transistors or N-type field effect transistors.

3. The integrated circuit according to claim 1, wherein the plurality of dynamic registers further comprise a third dynamic register arranged in a third row adjacent to the second row but not adjacent to the first row, the third dynamic register comprises a third tristate gate, the second tristate gate further comprises a third FET with an opposite polarity to the first FET, the third tristate gate comprises a fourth FET with the same polarity as the third FET, the third FET is adjacent to the fourth FET, the third FET and the fourth FET use a second polysilicon pattern continuously extending across a second boundary between the second row and the third row as a gate terminal to receive a same second control signal that is complementary to the first control signal.

4. The integrated circuit according to claim 3, wherein the first polysilicon pattern and the second polysilicon pattern are aligned in a column direction.

5. The integrated circuit according to claim 1, wherein the first tristate gate further comprises a fifth FET, the second tristate gate further comprises a third FET, the polarities of the fifth FET and the third FET are opposite to that of the first FET, gate terminals of the fifth FET and the third FET receive a second control signal complementary to the first control signal, and a drain terminal of the first FET and a drain terminal of the fifth FET are coupled together to provide the output data signal of the first dynamic register.

6. The integrated circuit according to claim 5, wherein the first tristate gate further comprises a sixth FET and a seventh FET, a polarity of the sixth FET is opposite to that of the first FET, a polarity of the seventh FET is same as that of the first FET, a drain terminal of the seventh FET is coupled to a source terminal of the first FET, a drain terminal of the sixth FET is coupled to a source terminal of the fifth FET, gate terminals of the sixth FET and the seventh FET are coupled together to receive the input data signal of the first dynamic register, a source terminal of the sixth FET is coupled to one of a power supply rail or a ground rail, and a source terminal of the seventh FET is coupled to another one of the power supply rail or the ground rail.

7. The integrated circuit according to claim 6, wherein source terminals of the first FET and the fifth FET are coupled together.

8. The integrated circuit according to claim 1, wherein the first tristate gate and the second tristate gate have a same logic circuit diagram.

9. The integrated circuit according to claim 1, wherein the first FET and the second FET share a same substrate region continuously extending across the first boundary.

10. The integrated circuit according to claim 1, wherein the first dynamic register and the second dynamic register share one of a power supply rail or a ground rail, and the one of the power supply rail or the ground rail is arranged at the first boundary.

11. The integrated circuit according to claim 1, wherein the first dynamic register and the second dynamic register comprise a dynamic latch.

12. The integrated circuit according to claim 1, wherein the first tristate gate and the second tristate gate are implemented using complementary metal oxide semiconductor field effect transistors (CMOSs).

13. An operation chip, comprising at least one integrated circuit according to claim 1.

14. A computing apparatus, comprising:
at least one operation chip according to claim 13;
a control chip;
a power supply module; and
a radiator,
wherein the control chip is coupled to the at least one operation chip and is configured for controlling operation of the at least one operation chip;
wherein the power supply module is configured for providing power to the at least one operation chip and/or the control chip; and
wherein the radiator is configured for dissipating heat for the at least one operation chip, the control chip, and/or the power supply module.

15. The integrated circuit according to claim 2, wherein the first tristate gate further comprises a fifth FET, the second tristate gate further comprises a third FET, the polarities of the fifth FET and the third FET are opposite to that of the first FET, gate terminals of the fifth FET and the third FET receive a second control signal complementary to the first control signal, and a drain terminal of the first FET and a drain terminal of the fifth FET are coupled together to provide the output data signal of the first dynamic register.

16. The integrated circuit according to claim 8, wherein the first tristate gate further comprises a sixth FET and a seventh FET, a polarity of the sixth FET is opposite to that of the first FET, a polarity of the seventh FET is same as that of the first FET, a drain terminal of the seventh FET is coupled to a source terminal of the first FET, a drain terminal of the sixth FET is coupled to a source terminal of the fifth FET, gate terminals of the sixth FET and the seventh FET are coupled together to receive the input data signal of the first dynamic register, a source terminal of the sixth FET is coupled to one of a power supply rail or a ground rail, and a source terminal of the seventh FET is coupled to another one of the power supply rail or the ground rail.

17. The integrated circuit according to claim 9, wherein source terminals of the first FET and the fifth FET are coupled together.

18. The operation chip according to claim 16, wherein the plurality of dynamic registers further comprise a third dynamic register arranged in a third row adjacent to the second row but not adjacent to the first row, the third dynamic register comprises a third tristate gate, the second tristate gate further comprises a third FET with an opposite polarity to the first FET, the third tristate gate comprises a fourth FET with the same polarity as the third FET, the third FET is adjacent to the fourth FET, the third FET and the fourth FET use a second polysilicon pattern continuously extending across a second boundary between the second row and the third row as a gate terminal to receive a same second control signal that is complementary to the first control signal.

19. The operation chip according to claim 17, wherein the first polysilicon pattern and the second polysilicon pattern are aligned in a column direction.

20. The operation chip according to claim 16, wherein the first tristate gate further comprises a fifth FET, the second tristate gate further comprises a third FET, the polarities of the fifth FET and the third FET are opposite to that of the first FET, gate terminals of the fifth FET and the third FET receive a second control signal complementary to the first control signal, and a drain terminal of the first FET and a drain terminal of the fifth FET are coupled together to provide the output data signal of the first dynamic register.
